(19) United States
(12) Patent Application Publication
(10) Pub. No.: US 2019/0229232 A1
(43) Pub. Date: Jul. 25, 2019

(54) LIGHT SOURCE MODULE

(71) Applicant: Primax Electronics Ltd., Taipei (TW)

(72) Inventor: Chung-Yuan Chen, Taipei (TW)

(21) Appl. No.: 16/216,785

(22) Filed: Dec. 11, 2018

Related U.S. Application Data
(60) Provisional application No. 62/621,878, filed on Jan. 25, 2018.

(51) Int. Cl. H01L 33/06; H01L 33/50; H01L 33/00; H01L 33/52; H01L 33/30; H01L 33/48; H01L 33/62

(52) U.S. Cl. CPC H01L 33/06; H01L 33/50; H01L 33/0025; H01L 33/62; H01L 33/52; H01L 33/30; H01L 33/483; H01L 33/0062

(57) ABSTRACT

A light source module includes a LED die and a supporting base. The LED die emits a light beam. The LED die is embedded within the supporting base. The LED die is electrically connected with a first electric conduction structure of the supporting base through a conductor structure of the supporting base. Alternatively, the LED die is electrically connected with a second electric conduction structure of the supporting base.

### CROSS-REFERENCE TO RELATED APPLICATION

This application claims priority to U.S. Provisional Patent Application No. 62/621,878 filed Jan. 25, 2018, the contents of which are incorporated herein by reference.

### FIELD OF THE INVENTION

The present invention relates to a light source module, and more particularly to a light source module with high luminous efficiency.

### BACKGROUND OF THE INVENTION

Generally, a common light source uses a light emitting diode (LED) to generate a light beam. The illuminating principle of the light emitting diode will be described as follows. When a current is applied to a semiconductor material of Group III-V such as gallium nitride (GaN), gallium phosphide (GaP), gallium arsenide (GaAs) or indium phosphide (InP), electrons recombine with holes. Consequently, the extra energy is released from a multiple quantum well (MQW) in the form of photons, and the light beam visible to the eyes is generated.

The structure of a conventional LED die will be described as follows. FIG. 1 is a schematic cross-sectional view illustrating the structure of a conventional LED die. As shown in FIG. 1, the conventional LED die 1 has a multi-layered stack structure comprising a substrate 11, a P-type covering layer 12, a multiple quantum well 13, an N-type covering layer 14, a conducting film layer 15 (e.g., an ITO layer), a P-type electrode 16 and an N-type electrode 17. The P-type electrode 16 and the N-type electrode 17 are disposed on the top surface of the LED die 1. The P-type electrode 16 and the N-type electrode 17 are connected with wires according to a wire bonding process, which will be described later. The multiple quantum well 13 is disposed within the multi-layered stack structure. As mentioned above, the light beam of the LED die 1 is outputted from the multiple quantum well 13. Since the light beam is outputted upwardly from the multiple quantum well 13, a portion of the light beam is blocked and lost by the P-type covering layer 12, the conducting film layer 15, the P-type electrode 16 and the N-type electrode 17. Consequently, the overall luminous efficiency of the conventional LED die 1 to output the light beam upwardly is adversely affected. Generally, the overall luminance of the conventional LED die 1 is mainly dependent on the portion of the light beam leaked from the lateral side of the multiple quantum well 13. Consequently, the luminous efficiency of the conventional LED die 1 is not satisfied. In other words, the luminous efficiency of the conventional LED die 1 needs to be further improved.

FIG. 2 is a schematic cross-sectional view illustrating a light source module with the conventional LED die. The light source module 2 comprises a circuit board 21 and plural LED elements 22. The plural LED elements 22 are installed on the circuit board 21. For succinctness, only one LED element 22 is shown in FIG. 2. Each LED element 22 is electrically connected with the circuit board 21 to receive the current from the circuit board 21. Consequently, the LED element 22 emits a light beam. The light source module may be installed within an electronic device (not shown). Consequently, the electronic device has the function of outputting the light beam.

Generally, the light source modules are classified into two types. In the first type light source module, the circuit board 21 has a circuitry for controlling the operation of the LED element 22, and the electronic function of the electronic device to process associated electronic signals is implemented by another circuit board. In the second type light source module, the circuit board 21 has a circuitry for controlling the operation of the LED element 22, and the electronic function of the electronic device to process associated electronic signals is also implemented by the circuit board 21.

The LED element 22 of the light source module 2 is a package structure of a single LED die 1. In addition, the P-type electrode 16 and the N-type electrode 17 of the LED die 1 are connected with corresponding pins 211 of the circuit board 21 through wires 18. Consequently, the LED element 22 can receive the current from the circuit board 21. However, during the process of packaging the LED die 1, the LED die 1 is usually installed on a carrier plate 19. The volume of the carrier plate 19 and the retained height of the wires 18 are the main factors that increase the overall thickness of the package structure of the LED die 1. In other words, it is difficult to reduce the thickness of the light source module with the LED die 1. Of course, the increased thickness of the package structure of the LED die 1 is detrimental to the development of the electronic device toward small size and light weightiness.

With the improvement of technology and living quality, the user's or manufacturer's demands on the functions of the light source module are gradually increased. Basically, the light beam from the light source module provides the illuminating efficacy. In addition, the user or the manufacturer prefers that the light beam from the light source module has more applications. Consequently, some approaches were adopted. In accordance with an approach, an optical structure 23 (e.g., a photomask) is arranged in an optical path of the light beam from the LED element 22 of the conventional light source module 2. By the optical structure 23, the light beam from the LED element 22 undergoes a secondary optical treatment. For example, the secondary optical treatment includes a light-mixing operation, a light-guiding operation, a diffracting operation, a refracting operation, or the like. In such way, the light beam passing through the optical structure 23 generates a specified optical effect. As mentioned above, the constituents and the package structure of the conventional LED die 1 are detrimental to the miniaturization of the light source module. If the light source module is further equipped with the optical structure 23 to increase the optical effect, it is more difficult to reduce the thickness of the light source module.

In the associated industries, the manufacturer of the light source module and the manufacturer of the LED element 22 are different. Consequently, the manufacturer of the light source module often commissions the manufacturer of the LED element 22 to fabricate the LED element 22 according to the required optical specifications. After the manufacturer of the light source module 2 acquires the LED element 22 (i.e., the package structure of the LED die 1) from the manufacturer of the LED element 22, the LED element 22 and the circuit board 21 are combined together through a wire bonding process. However, since the manufacturer of the light source module often commissions the manufacturer of the LED element 22 to fabricate the LED element 22, some drawbacks occur. For example, the manufacturer of the LED element 22 is able to infer the commercial behaviors of the manufacturer of the light source module 2 according to the optical specifications provided by the manufacturer of the light source module 2. Actually, the manufacturer of the light source module 2 prefers to keep commercial confidence.

In other words, the conventional light source module and the manufacturing method of the light source module need to be further improved.

### SUMMARY OF THE INVENTION

An object of the present invention provides a light source module with high luminous efficiency, in which the LED die is embedded within a supporting base.

In accordance with an aspect of the present invention, there is provided a light source module. The light source module includes a supporting base and a LED die. The supporting base includes a first dielectric layer and a first electric conduction structure. The first electric conduction structure is located over the first dielectric layer. A trench is formed in the first dielectric layer. The trench is extended from a top surface of the first dielectric layer. A conductor structure is formed on an inner surface of the trench and electrically connected with the first electric conduction structure. The LED die is disposed within the trench and electrically connected with the first electric conduction structure through the conductor structure. The LED emits a light beam.

In accordance with another aspect of the present invention, there is provided a light source module. The light source module includes a supporting base and a LED die. The supporting base includes a first electric conduction structure, a first dielectric layer, a second electric conduction structure, a second dielectric layer and a perforation. The first dielectric layer is arranged between the first electric conduction structure and the second electric conduction structure. The second electric conduction structure is arranged between the first dielectric layer and the second dielectric layer. The perforation runs through the first electric conduction structure and the first dielectric layer. The LED die is disposed within the perforation and electrically connected with the second electric conduction structure. The LED emits a light beam.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating the structure of a conventional LED die;

FIG. 2 is a schematic cross-sectional view illustrating a light source module with the conventional LED die;

FIG. 3 is a schematic cross-sectional view illustrating a light source module according to a first embodiment of the present invention;

FIG. 4 is a schematic top view illustrating the luminous layer of the light source module according to the first embodiment of the present invention;

FIG. 5 is a schematic bottom view illustrating a portion of the light source module according to the first embodiment of the present invention;

FIG. 6 is a schematic cross-sectional view illustrating a light source module according to a second embodiment of the present invention;

FIG. 7 is a schematic cross-sectional view illustrating a light source module according to a third embodiment of the present invention;

FIG. 8 is a schematic cross-sectional view illustrating a light source module according to a fourth embodiment of the present invention;

FIG. 9 is a schematic cross-sectional view illustrating a light source module according to a fifth embodiment of the present invention; and

FIG. 10 is a schematic cross-sectional view illustrating a light source module according to a sixth embodiment of the present invention.

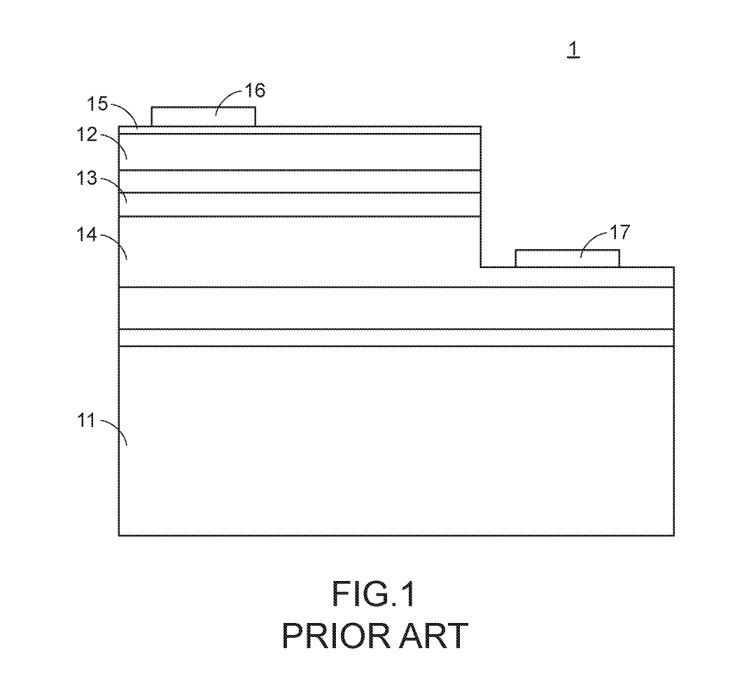

### DETAILED DESCRIPTION OF THE PREFERRED EMBODIMENT

For solving the drawbacks of the conventional technologies, the present invention provides a light source module. First of all, the structure of the light source module will be described as follows.

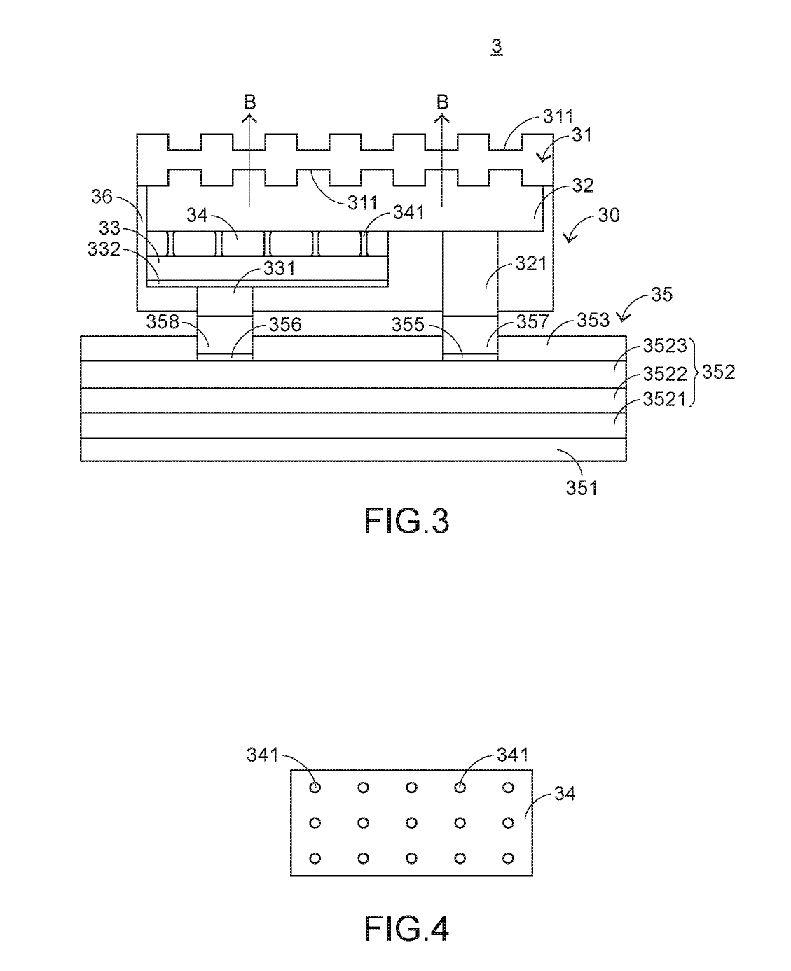

FIG. 3 is a schematic cross-sectional view illustrating a light source module according to a first embodiment of the present invention. As shown in FIG. 3, the light source module 3 comprises a substrate 31, a first covering layer 32, a second covering layer 33, a luminous layer 34, a supporting base 35 and a first passivation layer 36. The first covering layer 32 is disposed on the bottom surface of the substrate 31 for allowing a first current to go through. The second covering layer 33 is located under the first covering layer 32 for allowing a second current to go through. The luminous layer 34 is arranged between the first covering layer 32 and the second covering layer 33. In response to the first current and the second current, the luminous layer 34 emits a light beam B. After the light beam B is transmitted through the substrate 31, the light beam B is projected to the surroundings. The first covering layer 32, the second covering layer 33 and the luminous layer 34 are stack structures that are formed of semiconductor material of Group III-V. In addition, electrons recombine with holes to generate the light beam B. In an embodiment, the first covering layer 32 is an N—GaN covering layer, the second covering layer 33 is a P—GaN covering layer, and the luminous layer 34 is a multiple quantum well. The examples of the first covering layer, the second covering layer and the luminous layer are not restricted.

Please refer to FIGS. 3 and 4. FIG. 4 is a schematic top view illustrating the luminous layer of the light source module according to the first embodiment of the present invention. The luminous layer 34 comprises plural openings 341. The plural openings 341 are uniformly distributed in the luminous layer 34. Moreover, the plural openings 341 run through the top surface of the luminous layer 34 and the bottom surface of the luminous layer 34. Since the plural openings 341 are uniformly distributed, the density of the first current and the density of the second current are more uniform. Consequently, the light beam B is uniformly outputted from the luminous layer 34.

The substrate 31 comprises plural microstructures 311, which are formed on the top surface and the bottom surface of the substrate 31. Due to the microstructures 311, the total internal reflection of the light beam B within the substrate 31 will be avoided. In other words, the arrangement of the microstructures 311 can facilitate projecting the light beam B to the surroundings through the substrate 31. In this embodiment, the microstructures 311 are formed on the top surface and the bottom surface of the substrate 31 by using any other appropriate method (e.g., an etching process). Moreover, light source module 3 further comprises a first contact pad 321 and a second contact pad 331. The first contact pad 321 is located under the first covering layer 32 and electrically connected with the first covering layer 32. The second contact pad 331 is located under the second covering layer 33 and electrically connected with the second covering layer 33. Preferably, the second covering layer 33 further comprises a transparent conductive layer 332. The transparent conductive layer 332 is disposed on the bottom surface of the second covering layer 33 for assisting in the electric conduction of the second covering layer 33.

In this embodiment, a LED die 30 is defined by the substrate 31, the first covering layer 32, the second covering layer 33, the luminous layer 34 and the first passivation layer 36 collaboratively. After the LED die 30 and the supporting base 35 are combined together, the light source module 3 is produced.

Please refer to FIG. 3 again. The supporting base 35 is electrically connected with the first covering layer 32 and the second covering layer 33. In addition, the supporting base 35 comprises a dielectric layer 351, an electric conduction structure 352 and a second passivation layer 353. The electric conduction structure 352 is arranged between the dielectric layer 351 and the second passivation layer 353. The dielectric layer 351 is made of an insulation material and used for providing insulation. The electric conduction structure 352 is electrically connected with the LED die 30. The second passivation layer 353 is used for protecting the dielectric layer 351 and the electric conduction structure 352. In addition, the portion of the light beam B projected to the supporting base 35 can be reflected by the second passivation layer 353. Consequently, the light beam B is projected to the surroundings through the substrate 31.

In this embodiment, the supporting base 35 further comprises a first electrode 355, a second electrode 356, a first metallic coupling block 357 and a second metallic coupling block 358. In this embodiment, the electric conduction structure 352 comprises a copper foil layer 3521, a first metal connection layer 3522 and a second metal connection layer 3523. The second metal connection layer 3523 is disposed on the first metal connection layer 3522. The second metal connection layer 3523 and the first metal connection layer 3522 are combined together to reflect the light beam B. Both of the first electrode 355 and the second electrode 356 are disposed on the second metal connection layer 3523. The first metallic coupling block 357 is disposed on the first electrode 355. Moreover, the first electrode 355 and the first contact pad 321 of the first covering layer 32 are combined with each other through the first metallic coupling block 357. Similarly, the second metallic coupling block 358 is disposed on the second electrode 356. Moreover, the second electrode 356 and the second contact pad 331 of the second covering layer 33 are combined with each other through the second metallic coupling block 358. In other words, the supporting base 35 is electrically connected with the first covering layer 32 and the second covering layer 33 through the first metallic coupling block 357 and the second metallic coupling block 358, respectively.

The constituents of the electric conduction structure 352 are not restricted. That is, the constituents of the electric conduction structure 352 may be varied according to the practical requirements. In a variant example, the electric conduction structure 352 comprises the copper foil layer 3521 but does not comprise the first metal connection layer 3522 and the second metal connection layer 3523. Moreover, both of the first electrode 355 and the second electrode 356 are disposed on the copper foil layer 3521. In another variant example, the electric conduction structure 352 comprises the second metal connection layer 3523 but does not comprise the copper foil layer 3521 and the first metal connection layer 3522. In a further variant example, the electric conduction structure 352 comprises the copper foil layer 3521 and the second metal connection layer 3523 but does not comprise the first metal connection layer 3522.

As shown in FIG. 3, the substrate 31, the first contact pad 321 and the second contact pad 331 are exposed outside the first covering layer 32, the second covering layer 33 and the luminous layer 34. The first contact pad 321 and the second contact pad 331 are fixed on the supporting base 35 or the conventional carrier plate 19 through a direct coupling process (e.g., a welding process or any other appropriate coupling process). That is, the electric connection of the light source module 3 is established without the need of performing the wire boning process. Consequently, the overall thickness of the light source module 3 is reduced. The reduction of the thickness is helpful to achieve the slimness benefit of the light source module 3. Moreover, the first covering layer 32, the first contact pad 321, the second covering layer 33, the second contact pad 331 and the luminous layer 34 are covered by the first passivation layer 36. Consequently, these components are protected by the first passivation layer 36.

The first contact pad 321 is electrically connected with the first electrode 355 through the first metallic coupling block 357. The second contact pad 331 is electrically connected with the second electrode 356 through the second metallic coupling block 358. Consequently, the wire bonding process is omitted. Moreover, the heat generated by the LED die 30 is directly transferred to the underlying supporting base 35 through the first contact pad 321 and the second contact pad 331 via thermal conduction. Moreover, the heat is further dissipated to the surroundings through the supporting base 35. Since the supporting base 35 has a large area, the heat can be dissipated away more quickly. Since the heat is largely reduced, the influence of the heat on the luminous efficiency of the light source module 3 is largely reduced.

In an embodiment, the supporting base 35 is made of gold or silver to increase the electrical property and the scattering property. Preferably but not exclusively, the supporting base 35 is a flexible printed circuit board (FPC), a printed circuit board (PCB) or a copper plated resin board (PET). The flexible printed circuit board is formed by coating copper traces on a polyimide base (i.e., a PI base) and then performing a surface treatment. The printed circuit board is formed by coating copper traces on a fiberglass reinforced epoxy resin base (i.e., FR4 base) and then performing a surface treatment. The copper plated resin board is formed by coating copper traces on a polyethylene terephthalate base (i.e., PET base) and then performing a surface treatment.

In an embodiment, the first metallic coupling block 357 and the second metallic coupling block 358 are soldering material such as solder paste, silver paste, gold ball, solder ball or tin paste. The welding process includes but is not limited to a thermosonic process, a eutectic process or a reflow process. The first metal connection layer 3522 is made of copper or a copper-like metallic material. The second metal connection layer 3523 is made of gold, nickel, a gold-like metallic material or a nickel-like metallic material. Due to the properties of gold or nickel, the second metal connection layer 3523 provides higher reflectivity and higher bonding capability.

The following four aspects should be specially described.

Firstly, the copper foil layer 3521 is disposed on the top surface of the dielectric layer 351. Consequently, the top surface of the dielectric layer 351 is not smooth. After the first metal connection layer 3522 is formed on the top surface of the dielectric layer 351, the top surface of the dielectric layer 351 is smooth.

Secondly, the materials of the first metallic coupling block 357 and the second metallic coupling block 358 are not restricted as long as they are made of conductive metallic materials. That is, the first metallic coupling block 357 is not restrictedly made of copper, and the second metallic coupling block 358 is not restrictedly made of gold or nickel.

Thirdly, in a preferred embodiment, the substrate 31 is a transparent or translucent sapphire substrate. Consequently, the light beam B generated by the luminous layer 34 is transmitted upwardly through the substrate 31 without being blocked. In other words, the number of times the light beam is reflected and the light loss percentage will be reduced, and the luminous efficiency will be enhanced. Moreover, due to this arrangement, the overall light-outputting area of the light source module 3 is increased. Moreover, since the substrate 31 comprises the concave-convex microstructures 311, the light beam B generated by the light source module 3 will not undergo the total internal reflection within the substrate 31. Consequently, the light beam B can be directly projected to the surroundings through the substrate 31. Under this circumstance, the light-outputting efficiency of the light source module 3 is enhanced. The experiments indicates that the light-outputting efficiency of the light source module 3 is 1.6-3 times the light-outputting efficiency of the conventional light source module.

Fourthly, the second passivation layer 353 of the supporting base 35 is made of an insulating material, and the second metal connection layer 3523, the first electrode 355 and the second electrode 356 are covered by the second passivation layer 353. Consequently, the junction between the first contact pad 321 and the first metallic coupling block 357 and the junction between the second contact pad 331 and the second metallic coupling block 358 will not generate the leakage current. Moreover, the second passivation layer 353 has the reflecting function. The portion of the light beam B that is projected downwardly will be reflected by the second passivation layer 353. Consequently, the light utilization efficiency is enhanced. In an embodiment, the second passivation layer 353 is an integral structure of an insulating material and a reflecting material. Alternatively, the insulating material and the reflecting material are separately formed as the second passivation layer 353.

Please refer to FIGS. 3 and 5. FIG. 5 is a schematic bottom view illustrating a portion of the light source module according to the first embodiment of the present invention. As shown in FIG. 3, the bottom surface of the first contact pad 321 and the bottom surface of the second contact pad 331 are at the same level so as to facilitate combining the first contact pad 321 and the second contact pad 331 with the supporting base 35. Moreover, a portion of the LED die 30 of the light source module 3 is shown in FIG. 5. As shown in FIG. 5, the areas of the first contact pad 321 and the second contact pad 331 occupy a large percentage of the bottom surface of the first passivation layer 36. The large areas of the first contact pad 321 and the second contact pad 331 are helpful for transferring the heat from the LED die 30 to the supporting base 35 through thermal conduction. Since the light source module 3 is not overheated, the luminous efficiency is not deteriorated.

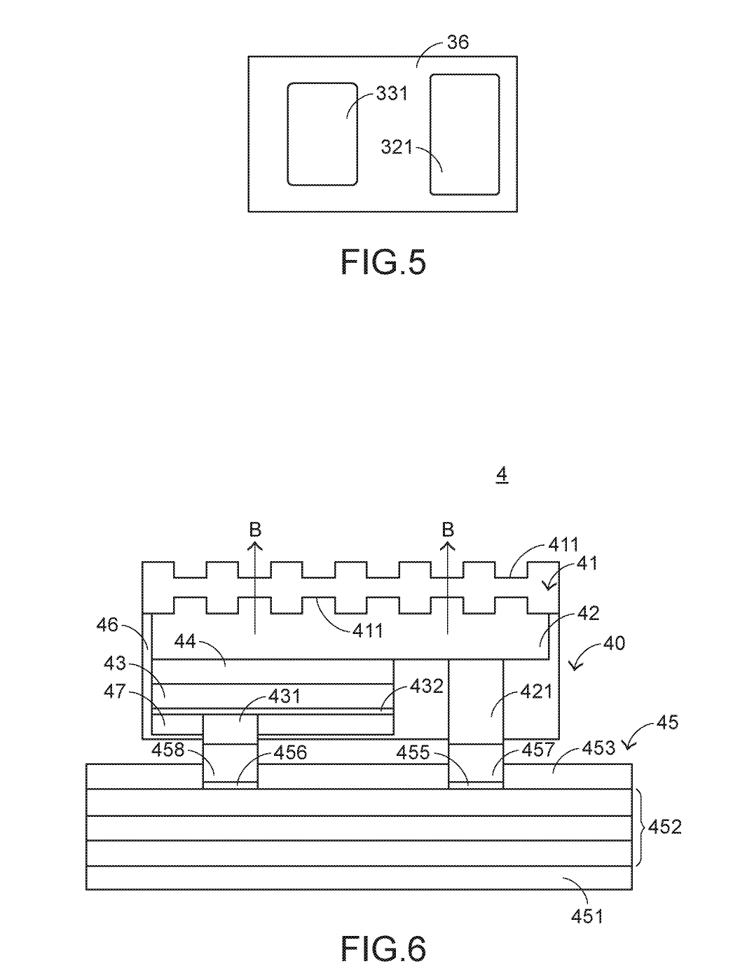

The present invention further provides a second embodiment, which is distinguished from the first embodiment. FIG. 6 is a schematic cross-sectional view illustrating a light source module according to a second embodiment of the present invention. As shown in FIG. 6, the light source module 4 comprises a substrate 41, a first covering layer 42, a second covering layer 43, a luminous layer 44, a supporting base 45, a first passivation layer 46 and a reflecting layer 47. The substrate 41 comprises plural microstructures 411. Moreover, light source module 4 further comprises a first contact pad 421, a second contact pad 431 and a transparent conductive layer 432. The first contact pad 421 is located under the first covering layer 42. The second contact pad 431 and the transparent conductive layer 432 are located under the second covering layer 43. The supporting base 45 comprises a dielectric layer 451, an electric conduction structure 452 and a second passivation layer 453, a first electrode 455, a second electrode 456, a first metallic coupling block 457 and a second metallic coupling block 458. In this embodiment, a LED die 40 is defined by the substrate 41, the first covering layer 42, the second covering layer 43, the luminous layer 44 and the first passivation layer 46 collaboratively. After the LED die 40 and the supporting base 45 are combined together, the light source module 4 is produced. In comparison with the first embodiment, the light source module 4 further comprises the reflecting layer 47. The structures and functions of the other components of the light source module 4 are similar to those of the first embodiment, and are not redundantly described herein.

The reflecting layer 47 is located under the second covering layer 43. The portion of the light beam B transmitted through the second covering layer 43 can be reflected by the reflecting layer 47. Consequently, the light beam B is projected to the surroundings through the substrate 41, and the light utilization efficiency is enhanced. In case that the transparent conductive layer 432 is located under the second covering layer 43, the reflecting layer 47 is disposed on the bottom surface of the transparent conductive layer 432. In other words, the light source module of this embodiment is equipped with a distributed Bragg reflector (DBR) between the luminous layer 44 and the supporting base 45. Consequently, the light-outputting efficiency of the light source module of this embodiment is increased when compared with the conventional light source module.

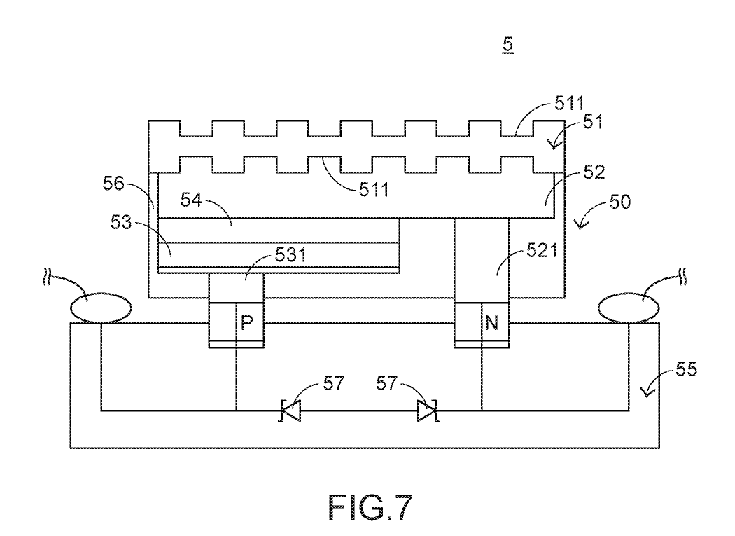

The present invention further provides a third embodiment, which is distinguished from the above embodiments. FIG. 7 is a schematic cross-sectional view illustrating a light source module according to a third embodiment of the present invention. As shown in FIG. 7, the light source module 5 comprises a substrate 51, a first covering layer 52, a second covering layer 53, a luminous layer 54, a supporting base 55, a first passivation layer 56 and plural Zener diodes 57. The substrate 51 comprises plural microstructures 511. Moreover, light source module 5 further comprises a first contact pad 521, a second contact pad 531 and a transparent conductive layer 532. The first contact pad 521 is located under the first covering layer 52. The second contact pad 531 and the transparent conductive layer 532 are located under the second covering layer 53. In this embodiment, a LED die 50 is defined by the substrate 51, the first covering layer 52, the second covering layer 53, the luminous layer 54 and the first passivation layer 56 collaboratively. After the LED die 50 and the supporting base 55 are combined together, the light source module 5 is produced. In comparison with the above embodiments, the light source module 5 further comprises the plural Zener diodes 57. The plural Zener diodes 57 are disposed on the supporting base 55. Moreover, the Zener diodes 57 and the luminous layer 54 are in inverse-parallel connection to form an electrostatic discharge (ESD) protection circuit. Consequently, the light source module is protected. The structures and functions of the other components of the light source module 5 are similar to those of the above embodiments, and are not redundantly described herein.

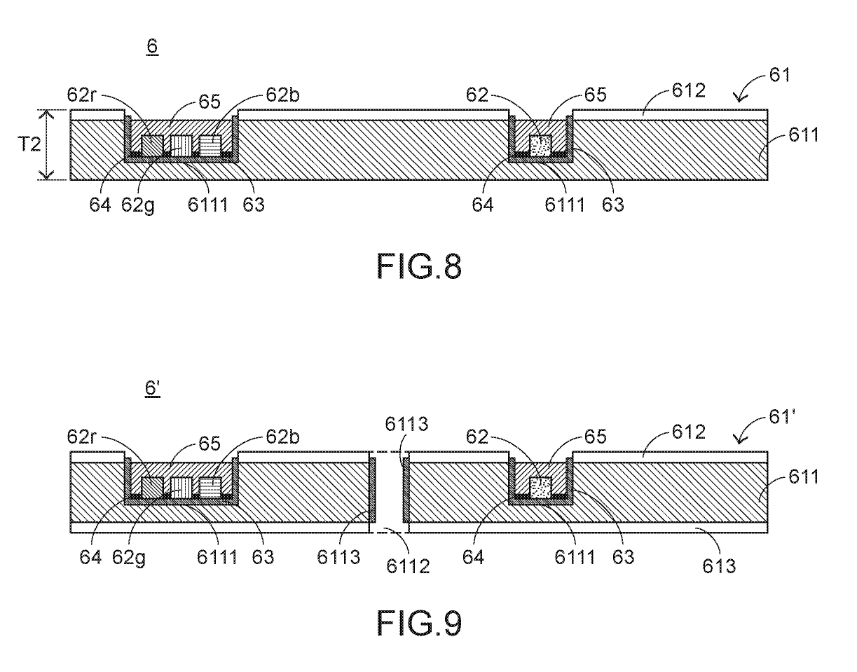

FIG. 8 is a schematic cross-sectional view illustrating a light source module according to a fourth embodiment of the present invention after being packaged. As shown in FIG. 8, the light source module 6 comprises a supporting base 61 and plural LED dies 62. The plural LED dies 62 are electrically connected with the supporting base 61. The structure of each LED die 62 is similar to the structure of the LED die 30, 40 or 50 of the above embodiments, and the structure of the supporting base 61 is similar to the structure of the supporting base 35, 45 or 55 of the above embodiments. The constituents of the LED die 62 and the constituents of the supporting base 61 are not redundantly described herein.

In comparison with the above embodiments, the following aspects of this embodiment are distinguished. At least one trench 6111 is formed in the dielectric layer 611 of the supporting base 61 and extended downwardly from a top surface of the dielectric layer 611. A conductor structure 63 is formed on a bottom surface and a sidewall of each trench 6111 and electrically connected with the electric conduction structure 612. For example, the conductor structure 63 is made of copper. The LED die 62 is disposed within the corresponding trench 6111. The LED die 62 receives the driving current from the electric conduction structure 612 through the conductor structure 63. The number of LED dies 62 disposed within each trench 6111 may be determined according to the practical requirement. For example, a LED die 62r for emitting the red light beam, a LED die 62g for emitting the green light beam and a LED die 62b for emitting the blue light beam are disposed within the same trench 6111. Preferably but not exclusively, the supporting base 61 is a single-sided circuit board. Optionally, the conductor structure 63 has a reflecting function. When the light beam is projected on the conductor structure 63, the light beam is reflected to the outside of the trench 6111.

Preferably but not exclusively, the light source module 6 further comprises a reflecting layer 64. The reflecting layer 64 is formed on at least a portion of the conductor structure 63. When the light beam is projected to the supporting base 61, the light beam is reflected by the reflecting layer 64 and projected to the outside of the trench 6111. In an embodiment, the light source module 6 further comprises an encapsulation layer 65. The encapsulation layer 65 is made of glue or nano-coating material. After the LED die 62 is disposed within the corresponding trench 6111, the encapsulation layer 65 is spread over the LED die 62 to protect the LED die 62.

In an embodiment, the trench 6111 is formed by a conventional process of forming a conductive hole in a double-sided circuit board to establish the electric connection between the top conductive layer and the bottom conductive layer of the circuit board. In accordance with the conventional process of forming the conductive hole, the conductive hole runs through the double-sided circuit board. In comparison with the conventional process, the trench 6111 of the present invention does not run through the supporting base 61. It is noted that the process of forming the trench 6111 is not restricted.

Preferably but not exclusively, the depth of the trench 6111 is nearly equal to or larger than the height of the LED die 62. In other words, the LED die 62 is embedded in the supporting base 61. According to the practical requirements, the encapsulation layer 65 is at the same level with the top surface of the dielectric layer 611 or the top surface of the electric conduction structure 612 (see FIG. 8) after the encapsulation layer 65 is spread over the LED die 62. Due to this design, the LED die 62 is not protruded over the supporting base 61. Consequently, the light source module 6 has the slim benefit and the applications of the light source module 6 are increased. Since the light source module 6 is slim, the electronic device with the light source module 6 has the benefits of small size, light weightiness and portability.

In some embodiments, a secondary optical structure (not shown) is additionally arranged in an optical path of the LED die 62 to achieve the required optical effect of the LED die 62. For example, the secondary optical structure is a lens. Since the LED die 62 of the light source module 6 is not protruded over the supporting base 61, the design flexibility of the secondary optical structure is enhanced. For example, it is not necessary to retain a space of the secondary optical structure to install the LED die 62.

In an embodiment, the encapsulation layer 65 is a nano-coating layer containing plural polymeric particles. According to the characteristics of the polymeric particles, the encapsulation layer 65 has the waterproof property, the hydrophobic property, the conductive property, the solderable property, the light-transmissible property, the concealment property, the hydrophobic property, the acid fog-resistant property, the salt fog-resistant property and/or the antiseptic property.

In an embodiment, the manufacturing process is specially designed to control the way of coating the encapsulation layer 65 on the LED die 62. Consequently, the optical characteristics are adjusted, and the required optical effect is achieved. For example, by changing the arrangement or the stacking form of the polymeric particles, the encapsulation layer has the light-mixing property. Consequently, the plural light beams from plural LED dies 62 are mixed together. Alternatively, by changing the arrangement or the stacking form of the polymeric particles, the plural light beams from plural LED dies 62 produce a specified light pattern or travel along a specified direction after passing through the polymeric particles.

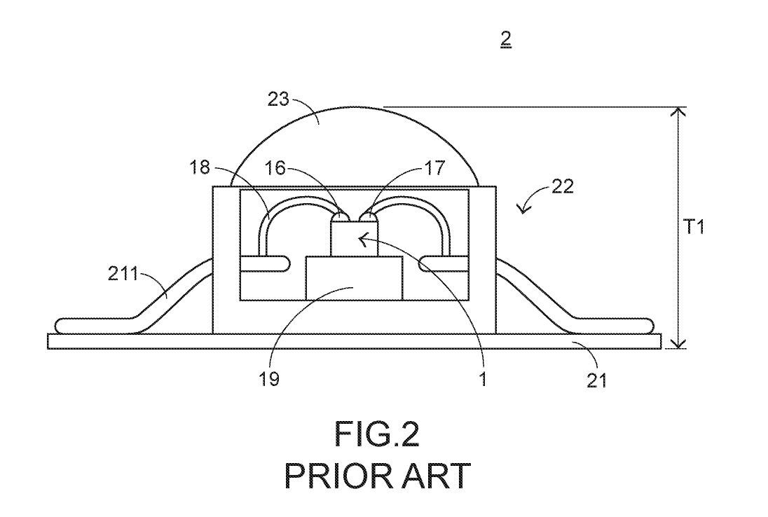

Please refer to FIG. 2 and FIG. 8 again. According to the conventional technology of installing the light source on the circuit board 21, the LED element 22 (i.e., the package structure of the LED die 1) is placed on the circuit board 21, and the LED element 22 and the circuit board 21 are connected with each other through wires 18 so as to form the light source module 2. For allowing the light source module 2 to generate a specified optical effect, an optical structure 23 (e.g., a photomask) is arranged in an optical path of the light beam from the LED element 22. The light source module 2 has a thickness T1. Generally, it is difficult to effectively reduce the overall thickness of the light source module 2. According to the present invention, the constituents of the LED die 62 are modified. Consequently, the LED die 62 is directly welded on the supporting base 61 without the need of using the wire bonding process. Moreover, the LED die 62 is not protruded over the supporting base 61. According to the present invention, the encapsulation layer 65 has the packaging, protecting and optically-treating functions. In this embodiment, the light source module 6 has a thickness T2. The thickness T2 of the light source module 6 is much smaller than the thickness T1 of the light source module 2.

In an embodiment, the light source module 6 is a stand-alone device. Alternatively, the light source module 6 is installed in an electronic device (not shown). Consequently, the electronic device has the function of emitting the light beam. In case that the light source module 6 is installed in the electronic device, the light source module 6 is classified into two types. In accordance with the first type, the supporting base 61 has a circuitry for controlling the operations of the LED dies 62. For example, the supporting base 61 provides the driving current to the LED dies 62. The electronic function of the electronic device to process associated electronic signals is implemented by another circuit board of the electronic device. In accordance with the second type, the supporting base 61 has a circuitry for controlling the operations of the LED dies 62, and the electronic function of the electronic device to process associated electronic signals is also implemented by the supporting base 61. It is noted that the applications of the light source module 6 and the functions of the supporting base 61 are not restricted.

The present invention further provides a manufacturing method of the light source module. The manufacturing method comprises the following steps. It is noted that the steps of the manufacturing method are not restricted.

In a step S1, the trench 6111 is formed in the supporting base 61.

In a step S2, the conductor structure 63 is formed on an inner surface of the trench 6111 and electrically connected with the electric conduction structure 612 by an electroplating process.

In a step S3, the at least one LED die 62 is disposed within the trench 6111.

In a step S4, the electric connection between the at least one LED die 62 and the supporting base 61 is established.

In a step S5, the at least one LED die 62 and the supporting base 61 are subjected to a photoelectric test.

In a step S6, the encapsulation layer 65 is spread over the at least one LED die 62 to package the at least one LED die 62.

In a step S7, the supporting base 61 is cut to have the desired shape, and thus the light source module 6 is produced.

In a step S8, the light source module 6 is subjected to the photoelectric test. If the photoelectric test passes, the produced light source module 6 can be normally operated.

From the above descriptions, the present invention provides the light source module and the manufacturing method of the light source module. The structure and the manufacturing method of the light source module are simplified. Consequently, the manufacturer of the light source module can directly implement the process of assembling and packaging the light source module without the need of commissioning the manufacturer of the light emitting diode to provide the conventional LED element (i.e., the package structure of the LED die). The manufacturer of the light emitting diodes is unable to infer the commercial behaviors and the packaging techniques (e.g., the optical effect provided by the package structure) of the manufacturer of the light source module. Since the designs about the light source module are not leaked out, the efficacy of keeping commercial confidence is achieved.

The above example of the light source module is presented herein for purpose of illustration and description only. It is noted that numerous modifications and alterations may be made while retaining the teachings of the invention. Two other embodiments of the light source module will be described as follows.

FIG. 9 is a schematic cross-sectional view illustrating a light source module according to a fifth embodiment of the present invention. The components of the light source module 6′ of this embodiment that are similar to that of the fourth embodiment are not redundantly described herein. In comparison with the fourth embodiment, the supporting base 61′ of the light source module 6′ is a double-sided circuit board. That is, the light source module 6′ further comprises another electric conduction structure 613 under the dielectric layer 611. The supporting base 61′ further comprises a conductive hole 6112. The conductive hole 6112 runs through the supporting base 61′. A conductor structure 6113 is disposed within the conductive hole 6112. For example, the conductor structure 6113 is made of copper. The electric conduction structure 612 and the electric conduction structure 613 are electrically connected with each other through the conductive hole 6112 and the conductor structure 6113 within the conductive hole 6112. The technologies about the double-sided circuit board are well known to those skilled in the art, and are not redundantly described herein.

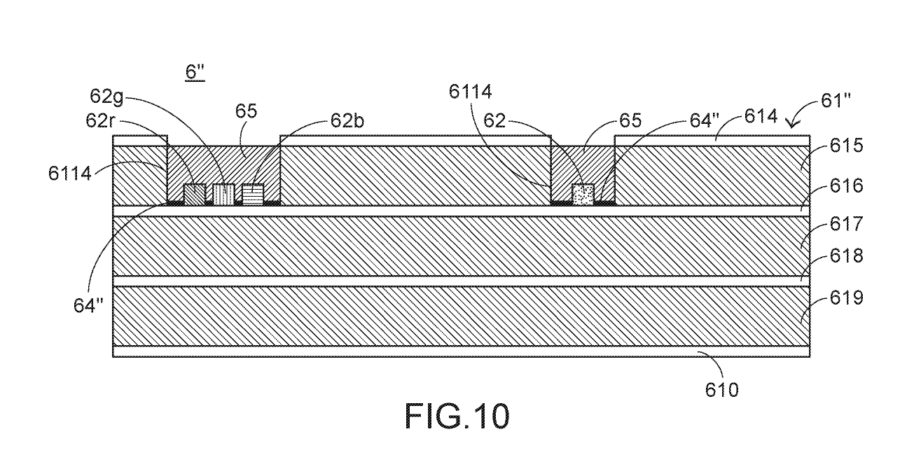

FIG. 10 is a schematic cross-sectional view illustrating a light source module according to a sixth embodiment of the present invention. The components of the light source module 6″ of this embodiment that are similar to that of the fourth embodiment are not redundantly described herein. In comparison with the fourth embodiment, the supporting base 61″ of the light source module 6″ is a multi-layered circuit board.

Please refer to FIG. 10 again. From top to bottom, the supporting base 61″ comprises a first electric conduction structure 614, a first dielectric layer 615, a second electric conduction structure 616, a second dielectric layer 617, a third electric conduction structure 618, a third dielectric layer 619 and a fourth electric conduction structure 610 sequentially. Any two of the first electric conduction structure 614, the second electric conduction structure 616, the third electric conduction structure 618 and the fourth electric conduction structure 610 are electrically connected with each other through the conductive holes (not shown) within the supporting base 61″ and the conductor structures within the conductive holes. The conductive holes are similar to the conductive hole 6112 as shown in FIG. 9, and are not redundantly described herein. The conductor structures are similar to the conductor structure 6113 as shown in FIG. 9, and are not redundantly described herein. The technologies about the multi-layered circuit board are well known to those skilled in the art, and are not redundantly described herein.

As shown in FIG. 10, a perforation 6114 runs through the first electric conduction structure 614 and the first dielectric layer 615. The LED die 62 is disposed within the perforation 6114 and electrically connected with the second electric conduction structure 616. Consequently, the LED die 62 can receive the driving current from the second electric conduction structure 616.

Preferably but not exclusively, the light source module 6″ further comprises a reflecting layer 64″. The reflecting layer 64 is formed on at least a portion of the second electric conduction structure 616. When the light beam is projected to the supporting base 61″, the light beam is reflected by the reflecting layer 64″ and projected to the perforation 6114. In an embodiment, the light source module 6″ further comprises an encapsulation layer 65. The encapsulation layer 65 is made of glue or nano-coating material. After the LED die 62 is disposed within the perforation 6114, the encapsulation layer 65 is spread over the LED die 62 to protect the LED die 62.

In an embodiment of forming the supporting base 61″, the first electric conduction structure 614 and the first dielectric layer 615 are formed on the second electric conduction structure 616 after the perforation 6114 is formed. It is noted that the process of forming the supporting base 61″ is not restricted.

Preferably but not exclusively, the depth of the perforation 6114 is nearly equal to or larger than the height of the LED die 62. In other words, the LED die 62 is embedded in the supporting base 61″. According to the practical requirements, the encapsulation layer 65 is at the same level with the top surface of the first dielectric layer 615 or the top surface of the first electric conduction structure 614 (see FIG. 10) after the encapsulation layer 65 is spread over the LED die 62. Due to this design, the LED die 62 is not protruded over the supporting base 61″. Consequently, the light source module 6″ has the slim benefit and the applications of the light source module 6″ are increased. Since the light source module 6″ is slim, the electronic device with the light source module 6″ has the benefits of small size, light weightiness and portability.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light source module, comprising:
a supporting base comprising a first dielectric layer and a first electric conduction structure, wherein the first electric conduction structure is located over the first dielectric layer, and a trench is formed in the first dielectric layer, wherein the trench is extended from a top surface of the first dielectric layer, and a conductor structure is formed on an inner surface of the trench and electrically connected with the first electric conduction structure; and
a LED die disposed within the trench and electrically connected with the first electric conduction structure through the conductor structure, wherein the LED emits a light beam.

2. The light source module according to claim 1, wherein the supporting base further comprises a reflecting layer, which is disposed on the conductor structure, wherein when the light beam is projected to the supporting base, the light beam is reflected by the reflecting layer and projected to an outside of the trench.

3. The light source module according to claim 1, wherein the LED die comprises:
a substrate;
a first covering layer disposed on a bottom surface of the substrate and electrically connected with the supporting base, wherein a first current flows through the first covering layer;
a second covering layer located under the first covering layer and electrically connected with the supporting base, wherein a second current flows through the second covering layer; and
a luminous layer arranged between the first covering layer and the second covering layer, wherein the luminous layer emits the light beam in response to the first current and the second current, and the light beam is projected to surroundings through the substrate.

4. The light source module according to claim 3, further comprising a first contact pad and a second contact pad, wherein the first contact pad is located under the first covering layer and electrically connected with the first covering layer, and the second contact pad is located under the second covering layer and electrically connected with the second covering layer.

5. The light source module according to claim 3, wherein the light source module further comprises a reflecting layer, which is located under the second covering layer, wherein when the light beam transmitted through the second covering layer is reflected by the reflecting layer, the light beam is projected to the surroundings through the substrate.

6. The light source module according to claim 1, wherein the light source module further comprises an encapsulation layer, which is disposed on the LED die.

7. The light source module according to claim 1, wherein a depth of the trench is larger than a height of the LED die, or the depth of the trench is substantially equal to the height of the LED die.

8. The light source module according to claim 1, wherein the supporting base further comprises a second electric conduction structure, and the second electric conduction structure is located under the first dielectric layer.

9. The light source module according to claim 1, wherein the supporting base further comprises a conductive hole, and an additional conductor structure is disposed within the conductive hole, wherein the first electric conduction structure and the second electric conduction structure are electrically connected with each other through the additional conductor structure.

10. The light source module according to claim 1, wherein when the light beam is projected to the supporting base, the light beam is reflected by the supporting base and the light beam is projected to surroundings through the LED die.

11. The light source module according to claim 1, wherein when the light beam is projected to the conductor structure, the light beam is reflected by the conductor structure and the light beam is projected to surroundings through the LED die.

12. A light source module, comprising:
a supporting base comprising a first electric conduction structure, a first dielectric layer, a second electric conduction structure, a second dielectric layer and a perforation, wherein the first dielectric layer is arranged between the first electric conduction structure and the second electric conduction structure, the second electric conduction structure is arranged between the first dielectric layer and the second dielectric layer, and the perforation runs through the first electric conduction structure and the first dielectric layer; and
a LED die disposed within the perforation and electrically connected with the second electric conduction structure, wherein the LED emits a light beam.

13. The light source module according to claim 12, wherein the supporting base further comprises a reflecting layer, which is disposed on the second electric conduction structure, wherein when the light beam is projected to the supporting base, the light beam is reflected by the reflecting layer and projected to an outside of the perforation.

14. The light source module according to claim 12, wherein the LED die comprises:
a substrate;
a first covering layer disposed on a bottom surface of the substrate and electrically connected with the supporting base, wherein a first current flows through the first covering layer;
a second covering layer located under the first covering layer and electrically connected with the supporting base, wherein a second current flows through the second covering layer; and
a luminous layer arranged between the first covering layer and the second covering layer, wherein the luminous layer emits the light beam in response to the first current and the second current, and the light beam is projected to surroundings through the substrate.

15. The light source module according to claim 14, wherein the light source module further comprises a reflecting layer, which is located under the second covering layer, wherein when the light beam transmitted through the second covering layer is reflected by the reflecting layer, the light beam is projected to the surroundings through the substrate.

16. The light source module according to claim 14, further comprising a first contact pad and a second contact pad, wherein the first contact pad is located under the first covering layer and electrically connected with the first covering layer, and the second contact pad is located under the second covering layer and electrically connected with the second covering layer.

17. The light source module according to claim 16, wherein the second electric conduction structure comprises:
a first metal connection layer located over the second dielectric layer; and
a second metal connection layer disposed on the first metal connection layer, wherein the first metal connection layer and the second metal connection layer are combined together to reflect the light beam.

18. The light source module according to claim 17, wherein the supporting base further comprises:
a first electrode disposed on the second electric conduction structure;
a second electrode disposed on the second electric conduction structure;
a first metallic coupling block disposed on the first electrode, wherein the first electrode and the first contact pad are combined with each other through the first metallic coupling block; and
a second metallic coupling block disposed on the second electrode, wherein the second electrode and the second contact pad are combined with each other through the second metallic coupling block.

19. The light source module according to claim 12, wherein a depth of the perforation is larger than a height of the LED die, or the depth of the perforation is substantially equal to the height of the LED die.

20. The light source module according to claim 12, wherein when the light beam is projected to the supporting base, the light beam is reflected by the supporting base and the light beam is projected to surroundings through the LED die.
